(19) United States
(12) Patent Application Publication
(10) Pub. No.: US 2023/0247895 A1
(43) Pub. Date: Aug. 3, 2023

(54) Surface-Modified Electron Transport Layer of Organic Light-Emitting Diode

(71) Applicant: LOYOLA UNIVERSITY CHICAGO, Chicago, IL (US)

(72) Inventors: Jacob W. Ciszek, Glenview, IL (US); Demetra Adrahtas, Minneapolis, MN (US)

(21) Appl. No.: 18/002,638

(22) PCT Filed: Jun. 25, 2021
(86) PCT No.: PCT/US2021/039035

§ 371 Date: Dec. 20, 2022

Related U.S. Application Data
(60) Provisional application No. 63/138,994, filed on Jan. 19, 2021.
(60) Provisional application No. 63/044,560, filed on Jun. 26, 2020.

(51) Int. Cl. H10K 85/10; C09D 5/24; H10K 85/60

(52) U.S. Cl. CPC H10K 85/111; C09D 5/24; H10K 85/6572; H10K 50/16

(57) ABSTRACT

Disclosed herein are surface-modified electron transport layers (“ETLs”) of organic light-emitting diodes (“OLEDs”). The ETLs comprise a ring-opening reaction product between a nitrogen-containing heterocycle of the ETL and an optionally substituted three-membered ring, such as an oxiranyl ring, an aziridinyl ring, or a thiiranyl ring, and methods of making the surface-modified ETLs.

### BACKGROUND

### Field of the Invention

The disclosure relates to surface-modified electron transport layers (“ETLs”) of organic light-emitting diodes (“OLEDs”) and methods of preparing the foregoing. More particularly, the disclosure relates to surface modification of a nitrogen-containing heterocycle of the ETLs via ring-opening reactions between the nitrogen-containing heterocycle and an optionally substituted three-membered heterocyclic ring.

### Brief Description of Related Technology

Conventional methods for fabricating organic light-emitting diode (“OLED”) involve depositing a low work function metal contact (e.g. Al) onto an electron transport layer (“ETL”). These depositions often result in sputter or thermal damage to the ETL, which manifests in higher driving voltages, high leakage current, metal penetration and/or ion damage. See Gao et al., Mater. Sci. Eng. R Rep. 2010 68 (3) 38-87.

Molecular materials currently dominate the massive organic light emitting diode (OLED) market ($26.5 billion in 2018, 22% per year growth projected, led by a recent 61% and 58% increase in OLED TV and smart watch panels, respectively). The success of OLED is also a bit deceiving, though. Top contact damage in OLED devices continues to vex industry with substandard protective layers proliferating.

Known technologies for addressing top contact penetration are as follows. In the first technology, a physically deposited interlayer on top of the ETL impedes the penetration of the metal atoms. More than 20 metal inorganic interlayers have been tried. These problems include the intermixing of these new layers with the ETL (for example CrOx is deposited via the same thermal process as the top contact), thermal damage, and the creation of additional electronic interfaces in the device. Even academically favored LiF, which is effective at lowering metal penetration, has not found widespread use in industry due to its propensity to generate diffusive lithium which migrates through the semiconductor. The second technology incorporates heteroatoms into the ETL. This requires a complete redesign of the layer, new electronics, and has been attempted for the last 20 years with little success. The third technology has been least effective to date. In this technology, physically deposited molecules containing heteroatoms (O, N, S) are introduced to react with the incoming metal. It is known that penetration and diffusion of metal are inversely related to its ability to react with the top-most layer. These materials have also been deposited at much lower temperatures than the inorganic interlayer technologies. This third technology has limited effectiveness due to a myriad of problems. Most significantly, the ideal functional groups (thiols, carboxylate, hydroxyls) are difficult to incorporate into molecules that can be used in deposition systems either because of the lack of stability at high temperatures, lack of volatility or both. Additionally, reaching high density of these groups is difficult to design into the molecules due to the stability/volatility issues.

Accordingly, there is a need for ETLs having a surface layer displaying three properties. One, the added surface layer should contain a metal-binding functional group that should be exposed at the top of the surface layer rather than embedded within it. Two, the functional group should be chosen to maximize the interaction/bond formed with the deposited metal. Three, the areal coverage of the metal-binding functional group over the surface should be uniform and of high density. Surface layers meeting these criteria will be able to facilitate formation of high quality metal contacts on top of the ETL layer.

Moreover, surface layers contain a high degree of tunability which is necessary to install the desired functional groups, and the specificity of the chemistry means that it is possible to design a surface layer where the functional groups are available at the surface. Their thickness (1-2 nm) minimizes overall change to the electronic band structure of the device and makes them ideal for these applications. There have been some initial attempts to functionalize organic semiconductors in this manner, but none have previously been successful.

Accordingly, there is a need for protective layers for ETL materials that can address these performance issues.

### SUMMARY

In one aspect, provided herein is a surface-modified electron transport layer (“ETL,” e.g., a modified ETL) of an organic light-emitting diode (“OLED”), the ETL comprising a ring-opening reaction product between a nitrogen-containing heterocycle of the ETL and one or more of an optionally substituted three-membered ring selected from the group consisting of an oxiranyl ring, an aziridinyl ring, and a thiiranyl ring. In some embodiments, the nitrogen-containing heterocycle comprises an imidazole. In some embodiments, the imidazole comprises 2,2′,2″-(1,3,5 benzinetriyl)-tris(1-phenyl-1-H-benzimidazole) (“TPBi”). The ring opening method of the disclosure also can be performed on any ETL layer that includes an appropriate nucleophilic nitrogen atom. Suitable ETL layers include, for example, phenanthrolines. Examples of phenanthrolines include bathocuproine (BCP) and bathophenanthroline (BPhen). Thus, in some embodiments, the nitrogen-containing heterocycle comprises a phenanthroline.

In some embodiments, the ring opening product comprises a monomer of the optionally substituted three-membered ring. In various embodiments, the ring opening product comprises a dimer of the optionally substituted three-membered ring. In some cases, the ring opening product comprises a trimer of the optionally substituted three-membered ring. In various cases, the ring opening product comprises a tetramer of the optionally substituted three-membered ring. In some embodiments, the ETL (e.g., the modified ETL) is substantially free of a polymerization product between the nitrogen-containing heterocycle, e.g., imidazole or phenanthroline, and the optionally substituted three-membered ring. For example, in some embodiments, the ETL (e.g., the modified ETL) suitably is substantially free from ring-opening reaction products having 5 or more, 4 or more, 3 or more, or 2 or more monomer units corresponding to the optionally substituted three-membered ring.

In some embodiments, the ETL (e.g., the modified ETL) comprises: a reacted ETL surface layer, wherein the surface layer can comprise a monolayer or a bilayer of the ring-opening reaction product; and an ETL bulk layer substantially free from the ring-opening reaction product. The ETL surface layer can be a monolayer, although it may more generally be 1-2 molecules thick in various embodiments, for example varying based on reaction conditions. The ETL surface layer corresponds to the location/surface of eventual cathode layer in an OLED. The ETL bulk layer corresponds to the portion of the ETL adjacent to other components of the OLED opposing the cathode layer, for example an EML layer.

In some embodiments, the OLED comprises a cathode layer in direct contact with the ETL, the cathode layer comprising a metal atom bonded to the ring-opened reaction product of the ETL. In an extension of the previous embodiment, the ETL can comprise: an ETL surface layer, wherein the surface layer can comprise a monolayer or a bilayer of the ring-opening reaction product; and an ETL bulk layer substantially free from the ring-opening reaction product and metal atoms of the cathode layer, for example as a result of the ETL surface layer preventing metal atom penetration into the ETL bulk layer during cathode layer formation. In some embodiments, the ETL is about 2 to 50 nm thick, or about 2 to 10 nm thick, for example representing the combined thickness of an ETL surface layer (e.g., 1-2 atoms or molecules thick) and an ETL bulk layer.

In various embodiments, the ring-opening reaction product is between the nitrogen-containing heterocycle, e.g., imidazole or phenanthroline, and an optionally substituted oxiranyl ring. In various cases, the metal atom of the cathode layer is selected from the group consisting of magnesium, calcium, aluminum, silver, copper, and combinations thereof. In various cases, the metal atom of the cathode layer is selected from the group consisting of aluminum, silver, copper, and combinations thereof. Pendant oxygen atoms (e.g., in a hydroxyl group or corresponding oxide zwitterion) in the ring-opening reaction product suitably can bond (e.g., covalently) with the metal atoms of the cathode layer to provide a stable attachment of the cathode layer at the cathode layer-ETL interface.

In some embodiments, the ring-opening reaction product is between the nitrogen-containing heterocycle, e.g., imidazole or phenanthroline, and an optionally substituted aziridinyl ring. In various embodiments, the metal atom of the cathode layer is selected from the group consisting of gold, silver, and combinations thereof. Pendant nitrogen atoms (e.g., in an amino group or corresponding nitride zwitterion) in the ring-opening reaction product suitably can bond (e.g., covalently) with the metal atoms of the cathode layer to provide a stable attachment of the cathode layer at the cathode layer-ETL interface.

In some cases, the ring-opening reaction product is between the nitrogen-containing heterocycle, e.g., imidazole or phenanthroline, and an optionally substituted thiiranyl ring. In various embodiments, the metal atom of the cathode layer is selected from the group consisting of gold, silver, and combinations thereof. Pendant sulfur atoms (e.g., in a thiol group or corresponding sulfide zwitterion) in the ring-opening reaction product suitably can bond (e.g., covalently) with the metal atoms of the cathode layer to provide a stable attachment of the cathode layer at the cathode layer-ETL interface.

Further provided herein are methods of preparing a surface-modified ETL comprising contacting a nitrogen-containing heterocycle of the ETL, e.g., an imidazole or phenanthroline of the ETL, with an optionally substituted oxiranyl ring, an optionally substituted aziridinyl ring, or an optionally substituted thiiranyl ring in a ring opening reaction to form the surface-modified ETL.

Further aspects of the disclosure will be apparent to those skilled in the art from a review of the following detailed description, taken in conjunction with the appended claims. Described hereinafter are specific embodiments of the disclosure with the understanding that the disclosure is illustrative, and is not intended to be limited to specific embodiments described herein.

### BRIEF DESCRIPTION OF THE FIGURES

FIG. 1 depicts a typical OLED stack with a coating of the disclosure on top of an ETL layer (left). An example imidazole, TPBi, is shown (right).

FIG. 2 depicts (a) the chemical structure of TPBi; (b) the structure of 1,2-dimethylimidazole and 1-methylbenzimidazole; and (c) an example of ring opening chemistry occurring from the reaction of TPBi.

FIG. 3 depicts betaine formation, which generates highly colored compounds easily detected via UV-visible spectroscopy.

FIG. 4 depicts formation of polymer based on repeated reaction of 1,2-dimethylimidazole with propylene oxide.

FIG. 5 depicts an atomic force microscope image showing the size of the grains for pentacene. This was correlated with reaction rate.

FIG. 6 depicts a material layer stack representing the common interfaces in OLED & OPV devices. Interfaces having a demonstrated surface layer chemistry are indicated on the right; interfaces without a demonstrated surface layer chemistry are indicated on the left.

FIG. 7 depicts the analysis of Ag electrodes thermally deposited onto tetracene samples (pristine on top, reacted on the bottom), which have been repeatedly bent.

FIG. 8 depicts the penetration of metal into treated (right) and untreated (left) ETLs. Untreated samples show significant metal penetration (left), and the presence of an interlayer prevents penetration (right).

FIG. 9 depicts the coating of a tetracene thin film via a Diels-Alder Reaction. Without wishing to be bound by theory, the added molecules contain functional groups (yellow) that eliminate interfacial contact problems.

FIG. 10 depicts IR spectra of selected regions of N-methylmaleimide (dashed line), tetracene (dotted), and the Diels-Alder adduct formed during reaction of these two (solid line). Spectra labeled with transmittance are the standard solution-synthesized samples. Spectra labeled with absorbance are from thin-films deposited on gold substrates. Gray bars show new peaks (bottom) correlate with the same peaks in the standard (top).

FIG. 11 depicts a schematic of a simple metal-semiconductor-metal device.

FIG. 12 (top) depicts cross-section TEM images of untreated (left) and coated (right) tetracene thin films after depositing 20 nm Ag top contacts. Metal penetration can be seen in the untreated sample as dark features that run vertically through the organic layer. The bottom row depicts SEM images of the untreated (left) and coated (right) films after depositing 6 nm Ag contacts. Clusters of Ag form on the untreated surface, while continuous films are seen on the reacted.

FIG. 13 depicts (left) ring opening chemistry to generate oxygen terminal groups for binding to metal, and (right) typical depth profile of a metal (Al) deposited onto an organic semiconductor. As an XPS probes lower layers, the Al signal (gray) decreases during the transition to the organic material

FIG. 14 illustrates representative OLED structures. With no cathode-ETL interlayer (left), significant penetration of the cathode can cause decreased light output. Both the chemically created interlayer (middle; according to the disclosure) and LiF interlayer (right) improve output via the improved interface with the cathode. The highly effective chemically created interlayer can allow for thinner ETL layers to be utilized while maintaining similar device performance.

### DETAILED DESCRIPTION

Disclosed herein is a surface-modified electron transport layer (“ETL”) of organic light-emitting diode (“OLED”) and methods of preparing the foregoing. The systems disclosed herein allow interfacial control between the ETL and metal (cathode) layer in an OLED using a single molecule thick coating (surface layer) to promote ETL-metal layer binding while limiting metal penetration into the ETL. Without intending to be bound by any particular theory, monolayer chemistry is capable of improving organic semiconductor mobility in OFETs and reduce metal penetration from top contacts in OLEDs. The ETLs disclosed herein are composed of a nitrogen-containing heterocycle film, e.g., an imidazole film or a phenanthroline film, that has been modified via a ring-opening reaction between an optionally substituted three-membered heterocyclic ring, such as a heterocyclic ring selected from the group consisting of an oxiranyl ring, an aziridinyl ring, and a thiiranyl ring, to form a betaine group. When a cathode layer is applied to the surface of the ETL, the negatively charged heteroatom of the betaine group of the ETL can bond to a metal of the cathode layer to result in superior OLED systems. In some embodiments, the ETL is about 2 to 50 nm thick. In various embodiments, the ETL is about 2 to 10 nm thick.

The surface layers of the disclosure solve the issues plagued by traditional OLEDs. For example, rather than incorporating groups into the molecules pre-deposition, the groups are added to existing molecules on the surface via chemistry.

Without intending to be bound by any particular theory, the chemistry of the disclosure allows avoidance of stability/volatility issues because the functional components are added in a second step. Small precursors can be added in (stoichiometric) ratios of one, two, or three per a nitrogen-containing heterocycle of the ETL, e.g., imidazole (such as TPBi) or phenanthroline—they start small and volatile, but combine with the nitrogen-containing heterocycle of the ETL, e.g., imidazole (such as TPBi) or phenanthroline scaffold to give a metal binding surface. Not only does the chemistry overcome the difficulty for creating these surfaces; they can also be much better defined than competing additive layers. Advantages/differentiators can be summarized thus:

1. A controllable surface provides maximized function and minimized side effects. These processes (and most surface chemistries) are well known to give highly defined surface with good control over thickness, even down single molecule thick layers. Orientation of the added molecules is also controlled and the small precursors can be oriented towards the incoming metal contact. The chemistry can be tuned to reach densities that are often incompatible with other deposition methods.

2. Highly tailorable to the metal. Industry uses either Al for a standard top contact, or Mg/Ag for an inverted configuration. By utilizing the chemistry disclosed herein, the added groups are highly tailorable. For example, in the surface layers of the disclosure, oxygen atoms are added to the surface, but simply by changing the precursor to episulfide, sulfur groups can be added via the same reaction.

3. Deposits Exclusively on the ETL. The chemistry of the disclosure specifically reacts only with the ETL. As such, other areas of the device do not have be covered (masked) to prevent unintended deposition.

4. Performance Edge over Inorganic Interlayers. When compared to inorganic materials (LiF, CrOx) the process of the disclosure occurs at lower temperatures, with larger (less penetrating) materials, and the chemically created interlayer can be less prone to metal diffusion.

Further, monolayer chemistry on traditional inorganic substrates (silicon, metals, indium tin oxide, etc.) has existed for nearly four decades, and was well established during the rise of organic molecular materials. In many instances, monolayers have been the difference between non-functional systems and viable technologies. In contrast, there is no comparable chemistry for working on the top of the organic materials. This is despite the fact that the majority of interfaces in OLEDs/OFETs are on top of an organic surface (FIG. 6).

In 2013, there were a few attempts to chemically alter the semiconductor surface, all of which utilized materials designed for modifying silicon. Diels-Alder chemistry was used to generate monolayer coatings on organic semiconductors as electron rich pi systems are a common motif for the majority of organic transistors. The present disclosure overcomes many of the challenges in generating defined chemistry on a molecular surface. For example, the weak van der Waals and π interactions that hold molecular materials together meant that confining the reaction to the surface was challenging. Weak interactions also mean the reaction can propagate across an unreactive surface from a single reactive site. Thermal control and prevention of accumulated precursors on the surface proved important for generating well-formed surface layers.

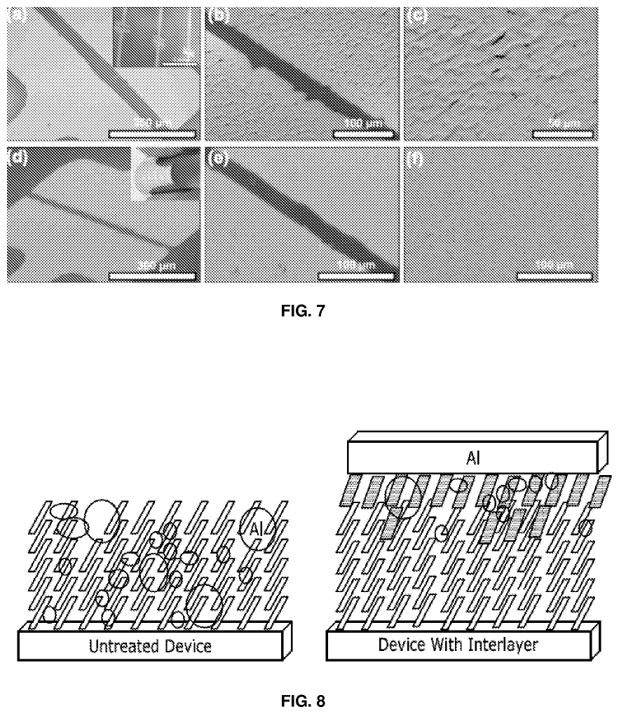

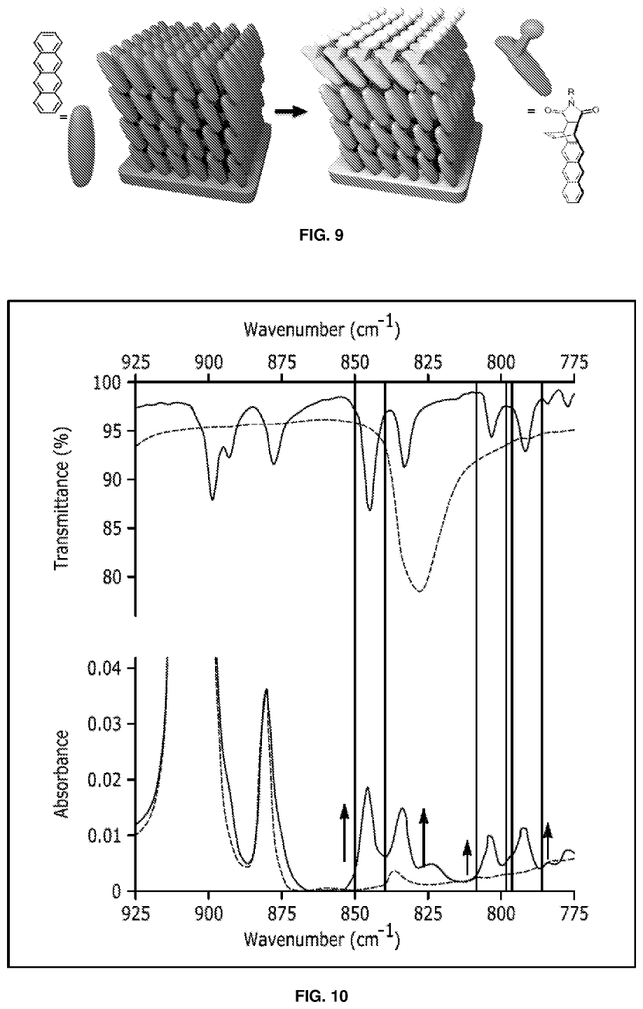

Just as importantly, the surface layer chemistry disclosed herein has overcome some of the challenges limiting organic materials for next generation processes. Specifically, as organic materials move into flexible/bendable applications, it becomes difficult to keep the top metal contact adhered to the organic material after repeated bending cycles. This device failure can be seen in FIG. 7 (top), where untreated devices show significant delamination of the silver after the bending cycles when imaged by scanning electron microscope (SEM, FIG. 7, panels a-c at different magnification levels). Rippled areas where the silver is free from the tetracene surface appear in as few as 10 bending cycles, while the tearing and flaking shown in panel c of FIG. 7 becomes prominent in 50 cycles. In contrast, the methods disclosed herein can use Diels-Alder chemistry to generate a surface layer on separate samples, and these display no obvious damage after 100 bending cycles (FIG. 7, panels d-f at different magnification levels).

The methods and surface layers disclosed herein have broad impacts, which fit into one of the following three categories: scientific advancement of surface chemistry on solid molecular materials, development of institutional and regional infrastructure, and increased scope of industrial processes. Some of these impacts are described below.

Impact 1: The direct impact which is explicitly discussed throughout is the reduced cost and higher performance of OLEDs. This leads to significant end product cost reduction (for the public) and allows these high quality displays to reach lower price point markets currently served by liquid crystal displays (LCD).

Impact 2: Cost reduction allows OLEDs to competitively enter the lighting market. OLED's ultimate efficiency is near that LED, while the ability to print the OLED across a large area means OLED is projected to fill an important and complementary role within lighting (e.g. signage). DOE targets suggest a roughly 50% cost reduction is necessary for all manufacturing components in order to enable high volume sales.

Impact 3: The disclosure provides a new tool for OLED fabrication facilities. Organic device fabrication continues to use traditional tools designed for the silicon industry, which are often suboptimal for organic materials.

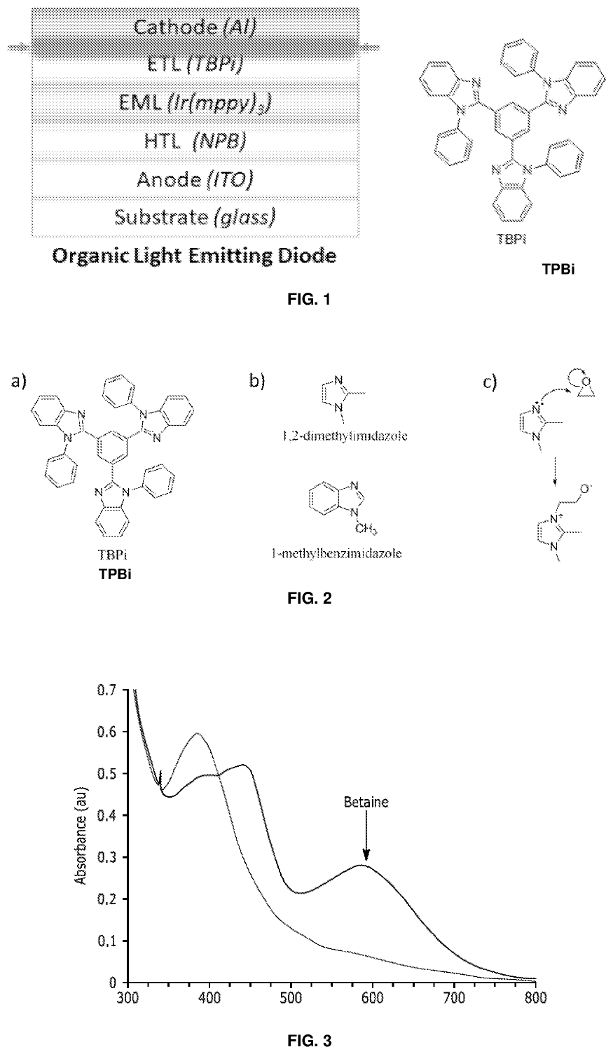

There is a compelling need for advanced processing of organic semiconductor surfaces. In a typical OLED device, 3+ organic layers are placed on top of a substrate (HTL, EML, ETL in FIG. 1) and are then coated with a metal cathode (Al). When this final layer is added, the metal is deposited at conditions far harsher than the underlying layers, generally through physical vapor deposition at 600-1000° C. or sputter coating (ion induced bombardment). As a result there is deposition based damage to the molecules themselves, while the deposited metal often begins to penetrate the organic material. In the best case scenario this generates higher driving voltages, high leakage current, metal penetration and/or ion damage. In the worst-case scenario, the metal penetrates an entire layer removing it from the circuit. As a result, industry has been forced to use excessively large ETL layers, and material cost for these layers now account for 30% of the total cost of the OLED stack. A well-designed chemically created interlayer, only 2-5 nm thick, can generate an idealized contact by installing chemical groups designed to bond to the cathode (FIG. 1. indicated by arrows). Furthermore this interlayer can allow for reduction in the ETL's thickness; currently much of the ETL is sacrificed to absorb incoming metal. As a result, materials cost for the OLEDs can be reduced.

The surface layer chemistry disclosed herein caps the OLED stack and inhibits the diffusion the top metal contact. The surface layers can eliminate cathode penetration into the electron transport layer (ETL, top of FIG. 8). This has two effects. It can improve external quantum efficiency or the measure of the number of emitted photons per number of injected electrons. It can also allow for reduction in the layer's thickness; currently much of the ETL is sacrificed to absorb incoming metal. Decreasing the thickness of the topmost organic layer (ETL, FIG. 8) is of great interest to industry as this layer now accounts for 30% of the total cost of the OLED stack.

In particular, the surface-modified ETLs disclosed herein can generate uniform thin films that experience minimal penetration and can also address device performance issues. These enhancements are further advantageous in that they reduce materials costs in the stacks. Also, lower surface defect density allows for thinner ETL and contact layers. In OLED systems, the ETL materials represent the largest cost in the stack, nearing 30% of its total cost (see OLED Supply/Demand and Capital Spending Report. Display Supply Chain Consultants 2018), and thus presents an opportunity for cost savings.

The ETL of the disclosure can comprise any suitable nitrogen-containing heterocycle. Suitable nitrogen-containing heterocycles can include 5- or 6-membered heterocyclic rings (e.g., aromatic or at least partially unsaturated rings) with 1, 2, or 3 nitrogen atoms in the ring. In some embodiments, the ETL comprises an imidazole or a phenanthroline (e.g., an imidazole- or phenanthroline-containing functional group). In some embodiments, the ETL comprises an imidazole. In some embodiments, the ETL comprises a phenanthroline. In some embodiments, the phenanthroline comprises bathocuproine (“BCP”) or bathophenanthroline (“BPhen”). In some embodiments, the phenanthroline comprises BCP. In some embodiments, the phenanthroline comprises BPhen. In some embodiments, the ETL comprises pyridines (e.g., 1,3-Bis(3,5-dipyrid-3-ylphenyl)benzene (B3PyPB)), pyrimidines (e.g., 4,6-Bis(3,5-di(pyridin-3-yl)phenyl)-2-methylpyrimidine, 4,6-Bis(3,5-di-3-pyridinylphenyl)-2-methylpyrimidine (B3PymPm)), pyrazines (e.g., pyrazino[2,3-f][1,10]phenanthroline-2,3-dicarbonitrile (PPDN)), triazines (e.g., 4,4′-bis(4,6-diphenyl-1,3,5-triazin-2-yl)biphenyl, 4,4′-bis-[2-(4,6-diphenyl-1,3,5-triazinyl)]-1,10-biphenyl (BTB)), quinolines (e.g., aluminum 8-hydroxyquinolinate (Alq3)). oxadiazoles (e.g., 1,3-bis[2-(4-tert-butylphenyl)-1,3,4-oxadiazo-5-yl]benzene (OXD-7)), triazoles (e.g., 3-(Biphenyl-4-yl)-5-(4-tert-butylphenyl)-4-phenyl-4H-1,2,4-triazole (TAZ)), or carbazoles (e.g., 1,3-bis(N-carbazolyl)benzene (mCP)), or a combination thereof.

The imidazole of the ETL can be any imidazole capable of functioning as an ETL. In some embodiments, the imidazole comprises 2,2′,2″-(1,3,5 benzinetriyl)-tris(1-phenyl-1-H-benzimidazole) (“TPBi”).

The three-membered ring that reacts with the nitrogen-containing heterocycle of the ETL generally includes a substituted or unsubstituted oxiranyl ring (e.g., oxirane compound), aziridinyl ring (e.g., aziridine compound), or thiiranyl ring (thiirane compound). The two carbon atoms in the 3-member oxiranyl, aziridinyl, or thiiranyl ring independently can be unsubstituted (i.e., containing two hydrogen atoms bound thereto), singly substituted (i.e., containing one hydrogen and one other non-hydrogen substituent bound thereto), or doubly substituted (i.e., containing two non-hydrogen substituents bound thereto). Examples of suitable non-hydrogen substituents include hydrocarbon groups, for example linear, branched, and/or cyclic, substituted or unsubstituted, saturated or unsaturated groups with 1 to 20 carbon atoms (e.g., at least 1, 2, 3, 4, or 6 and/or up to 2, 4, 6, 8, 10, 12, 15, or 20 carbon atoms). The non-hydrogen substituent can be an carbocyclic (e.g., aryl or partially or fully-saturated carbocyclic) or heterocyclic group. Non-limiting examples of heterocyclic groups include glycidol and vinylcyclohexene dioxide.

In some embodiments, the ring opening product comprises a monomer, a dimer, a trimer, or a tetramer of the optionally-substituted three-membered ring. In some embodiments, the ring opening product comprises a monomer of the optionally substituted three-membered ring. In various embodiments, the ring opening product comprises a dimer of the optionally substituted three-membered ring. In some cases, the ring opening product comprises a trimer of the optionally substituted three-membered ring. In various cases, the ring opening product comprises a tetramer of the optionally substituted three-membered ring. In some embodiments, the ETL is substantially free of a polymerization product between the nitrogen-containing heterocycle, e.g., an imidazole or phenanthroline, and the optionally substituted three-membered ring. As used herein, “substantially free” means the ETL comprises less than about 5%, e.g., less than about 4%, about 3%, about 2%, about 1%, about 0.1%, about 0.01%, or about 0.001% of a polymerization product between the nitrogen-containing heterocycle, e.g., an imidazole or phenanthroline.

In some embodiments, the OLED comprises a cathode layer in direct contact with the ETL. The cathode layer can comprise a metal atom bonded to the ring-opened reaction product of the ETL. In some embodiments, the cathode comprises one or metals such as magnesium, calcium, aluminum, copper, gold, silver, and combinations thereof (e.g., as an alloy).

In some embodiments, the modified ETL is produced via atomic layer deposition (ALD) systems, which are utilized in some OLED fabrication techniques.

In various embodiments, the ring-opening reaction product is between a nitrogen-containing heterocycle and an optionally substituted oxiranyl, aziridinyl, or thiiranyl ring. In various cases, the metal atom is selected from the group consisting of magnesium, calcium, aluminum, silver, copper, and combinations thereof. In various embodiments, the ring-opening reaction product is between a nitrogen-containing heterocycle and an optionally substituted oxiranyl ring. In various embodiments, the ring-opening reaction product is between an imidazole and an optionally substituted oxiranyl ring. In various embodiments, the ring-opening reaction product is between a phenanthroline and an optionally substituted oxiranyl ring. In various embodiments, the oxiranyl ring is unsubstituted. In various embodiments, the oxiranyl ring is substituted. Non-limiting examples of substituted oxiranes include trans-oxirane-2,3-dicarboxylic acid, conduritol B epoxide, diglycidyl 1,2-cyclohexanedicarboxylate, tris(2,3-epoxypropyl) isocyanurate, trimethylolpropane triglycidyl ether, methyl 2-methylglycidate, glycidol, vinylcyclohexene dioxide, thio-TEPA, or 2-(4-oxiranyl-butyl)-thiirane. In various cases, the metal atom is selected from the group consisting of magnesium, calcium, aluminum, silver, copper, and combinations thereof. In some embodiments, the ring-opening reaction product is between a nitrogen-containing heterocycle and an optionally substituted aziridinyl ring. In some embodiments, the ring-opening reaction product is between an imidazole and an optionally substituted aziridinyl ring. In various embodiments, the ring-opening reaction product is between a phenanthroline and an optionally substituted aziridinyl ring. In various embodiments, the aziridinyl ring is unsubstituted. In various embodiments, the aziridinyl ring is a substituted aziridinyl ring, for example tretamine, diaziquone, 2,5(1-aziridinyl)-3,5-dimethyl-1,4,-benzoquinone, or methybenzyl-aziridine-2-methanol. In various embodiments, the metal atom is selected from the group consisting of magnesium, calcium, gold, silver, and combinations thereof. In some cases, the ring-opening reaction product is between a nitrogen-containing heterocycle and an optionally substituted thiiranyl ring. In some cases, the ring-opening reaction product is between an imidazole and an optionally substituted thiiranyl ring. In various embodiments, the ring-opening reaction product is between a phenanthroline and an optionally substituted thiiranyl ring. In various embodiments, the thiiranyl ring is unsubstituted. In various embodiments, the thiiranyl ring is a substituted thiiranyl ring, for example 3-methylacrylatopropyl-1,2-episulfide, 2-hydroxymethylthiirane, Bis(B-epithiopropyl)sulfide, 3-mercapto-1,2-propylenesulfide, bis(B-epithiopropyl)disulfide, 5,6-didesoxy-5,6-epithio-1,2-O-isopropyliden-a-I-idofuranose, 5,6-didesoxy-5,6-epithio-1,2-O-isopropyliden-a-I-glucofuranose, thiirane-2-carboxylic acid, thiirancarboxylic acid, 3-propylthiiran-2-methanol, or 1,1-bis(epithioethyl)methane. In various embodiments, the metal atom is selected from the group consisting of gold, silver, and combinations thereof.

The skilled artisan would understand and appreciate that the embodiments disclosed herein relating to specific nitrogen-containing heterocycles, such as TPBi, and/or specific three-membered rings, such as propylene oxide, are nonlimiting and applicable to any of the other nitrogen-containing heterocycles and three-membered rings disclosed herein, such as any imidazole-containing heterocycle and/or any oxiranyl ring, aziridinyl ring, or thiiranyl ring.

### TPBi System

The ring opening chemistry described herein can be developed using the functional groups within an imidazole, such as TPBi (FIG. 1), and the differences which arise when adapting these reactions to the surface can be analyzed. On the fundamental science side, there are three aspects to consider regarding the development of ring. First, while literature precedence suggests sufficient reactivity within the nitrogen functional group of the chemically related 1,2-dimethylimidazole (FIG. 2b), the reaction of the imidizaole, such as TPBi must be developed. This is accomplished by demonstrating reaction on simple substrates first (1-methylbenzimidazole, FIG. 2b) before moving to TPBi. Second, the nucleophilicity of the generated betaine product is such that polymerization is a possible side product of the reaction. Additionally the desired product (FIG. 2c) is uncommon. See Wang et al., Green Chem 2014, 16 (4), 2266-2272. Thus, the viability of the betaine must be confirmed and polymerization minimized/eliminated. Accordingly, a range of ring opening products including the sulfur analog of propylene oxide are screened. Third, the transition to a surface reaction means new phenomena such as subsurface consumption, adsorbate diffusion, and reactivity variation at facets can occur. See Deye et al., Langmuir 2017, 33 (33), 8140-8146 and Qualizza et al. Chem. Commun. 2013, 49 (40), 4495-4497. As the surface reactions of imidazole films, such as TPBi films, are completely unprecedented, transition or experience with transistor materials to imidzale, such as TPBi, is needed. See Deye et al. Langmuir 2017, 33 (33), 8140-8146; Deye et al., J. Phys. Chem. C 2018, 122 (27), 15582-15587; Qualizza et al., Commun. 2013, 49 (40), 4495-4497; and Piranej et al. CrystEngComm 2016, 18 (32), 6062-6068. Of the three, this is the most challenging.

### Solution Chemistry Development

The betaine product is known to be highly nucleophilic, but has only been reported in a handful of publications. See Wang et al., Green Chem 2014, 16 (4), 2266-2272. Thus, its viability by the reaction of 1,2-dimethylimidazole, 1-methylbenzimidazole, and TPBi with propylene oxide is demonstrated. This involves standard solution phase synthetic protocol. Reactions are monitored for conversion rate, and products are analyzed using spectroscopic methods such as nuclear magnetic resonance spectroscopy (NMR), infrared spectroscopy (IR), and mass spectrometry (MS). Kinetics are also easily assessed via UV-vis spectroscopy where the highly colored betaines display prominent absorption peaks (FIG. 3). See Bartucci et al., J. Org. Chem. 2014, 79 (12), 5586-5594. The work of Lu provides initial conditions the synthetic work. See Wang et al., Green Chem 2014, 16 (4), 2266-2272.

### Ring Opening Chemistry

Disclosed herein is a ring opening chemistry that generates a contact enhancing interlayer on top of a common ETL layer, e.g., TPBi, in order to eliminate deposition based damage. The coatings can be applied to a prototypical OLED device in order to demonstrate the standard metrics of performance (lifetime, efficiency) and those which particular to the interface such as driving voltage. The chemistry can then optimized for an industrial setting.

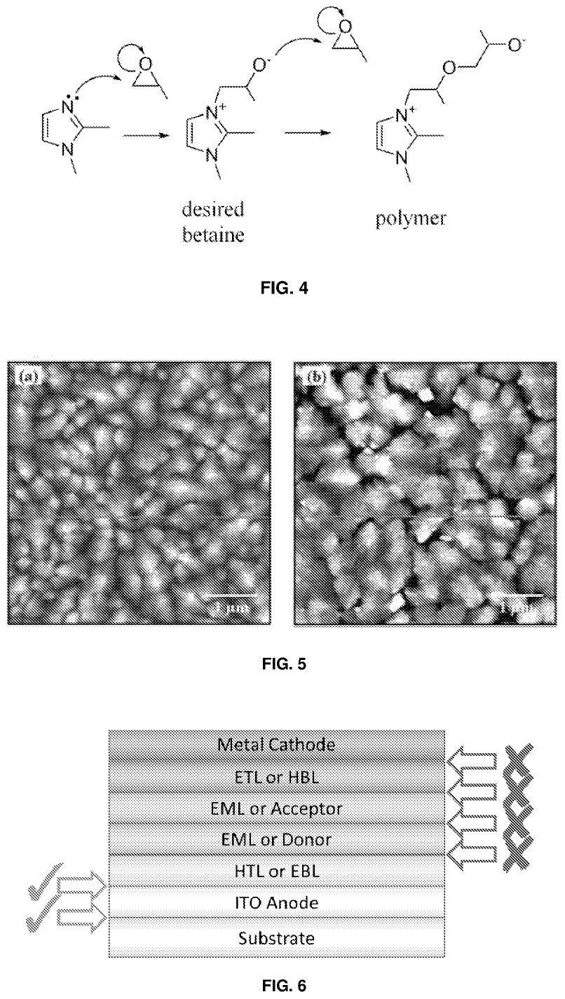

Of particular importance is discerning the betaine product's propensity to polymerize. In the case of the 1,2-dimethylimidazole, the generated products are nucleophilic enough to react with carbon dioxide, let alone propylene oxide. Polymerization occurs when the desired product (FIG. 4, middle) continues to react with propylene oxide (FIG. 4, right). Polymerization is easily detected and can be apparent when 1,2-dimethylimidazole is reacted with propylene oxide in exactly a 1:1 ratio—the complete consumption of both materials indicates the formation of the desired betaine. Unreacted 1,2-dimethylimidazole is a clear indication of polymerization. Normally polymerization can be avoided by rapid mixing and careful control of the concentration of materials. In cases when this issue in unable to be avoided, the ring opening of other molecules such as lactams, lactones, or propylene sulfide can be examined.

### Surface Chemistry Development

As traditional reactions are adapted for coating surfaces, new components of the chemistry arise. Substrate molecules are now in a locked configuration as the surface, and thus the approach of a reactant towards the surface is now restricted. Many of these nuances with respect to transistor materials (pentacene, tetracene) can be found in, e.g., Deye et al., J. Phys. Chem. C 2018, 122 (27), 15582-15587; Qualizza et al., Commun. 2013, 49 (40), 4495-4497; Piranej et al. CrystEngComm 2016, 18 (32), 6062-6068; and Hopwood et al., Chem. Commun. 2018. Briefly, surface adaption means the surface must be examined for subsurface consumption, adsorbate diffusion, and reactivity variation at facets. Without wishing to be bound by theory, the reaction rate can be accelerated via various techniques including but not limited to reaction under high pressure, reaction under high temperature, acid (e.g., HCl) catalysis, and/or microwave heating.

A) Subsurface consumption. In terms of subsurface consumption, the molecules of the surface are only loosely held together. Accordingly, the surface can be disturbed at high enough temperature, allowing reactants to diffuse into the film. This destruction of the surface must be weighed against the acceleration of reaction rates (allowing for quicker reaction). To check for surface degradation, the TPBi surface is reacted at various temperatures. In an ideal case, no more than about 2-5% (corresponding to the surface material) is consumed, regardless of temperature (if the entire film is 40-50 molecules thick, then 2-5% corresponds to 1-2 molecules thick, i.e. the surface). Polarization modulation infrared reflection absorption spectroscopy (PM-IRRAS) has been shown to be ideal in assessing film consumption. In cases when PM-IRRAS shows the consumption of the film, this is weighed against higher rates of reaction. In this instance, an optimum temperature is sought which will leave the surface intact, but allow complete coverage to be reached.

B) Surface Morphology Effects. In terms of reaction facets, here the packing of the molecules in the film determines whether the reactants can reach the nitrogen of the imidazole in order to react. See Qualizza et al., Chem. Commun. 2013, 49 (40), 4495-4497. In previous examples, it was found that the orientation of the surface limits reactivity. The TPBi has three nitrogen containing imidazole rings, and as such is unlikely to display any diminished reaction (at least one is likely to be oriented towards the surface). The reactivity of the surface and whether it displays and correlation with the size of the TPBi domains on the surface (FIG. 5) and with their orientation (determined via XRD) was considered. Similar methodology has been performed on transistor materials, with the domain size being controlled by deposition temperature. Deye et al., J. Phys. Chem. C 2018, 122 (27), 15582-15587.

C) Surface Coverage Assessment. Device characteristics (including metal penetration, contact uniformity, and charge injection) are all a function of surface composition and the uniformity of any coating applied to the system. Average surface composition can be detected via XPS, while nanoscale coverage can be assessed via a Neaspec NanoFTIR/NIM AFM.

### Minimizing ETL Layer Thickness, Increasing Yields

(A) Metal Penetration—A focus of this disclosure is to improve metal contact deposition via thin coatings. These coating can be compared to untreated substrates and substrates with a thin (1 nm) layer of LiF to assess their effects on the top contact. LiF is a representative method for treating eliminate contact issues which include LiF (Chou et al. Solid-State Electron. 2011, 64 (1), 1-5), alkanes (Göllner et a., Adv. Mater. 2010, 22 (39), 4350-4354), metal oxides (Alam et a., J. Photopolym. Sci. Technol. 2012, 25 (5), 659-664; Jeon et a., Synth. Met. 2009, 159 (23-24), 2502-2505).

The three systems (LiF, untreated, coated) are treated with thermally deposited Ag. Cross section TEM images can be used to assess the extent of metal penetration into the TPBi layer. Average defect density can be assessed along with average penetration of metal. This will allow examination of whether the layers can be made thinner, and by how much. Sputter coated or thermally deposited Al and similar studies can then be performed.

(B) Surface Uniformity—If the coating coverage is uniform, contacts that are uniform with less metals can be generated. For example, even at 20 nm untreated tetracene showed discontinuous Ag contact, in contrast to the coated samples where Ag contacts were continuous even at 6 nm. Ag contact coverage can be assessed as a function of contact thickness to assess to determine at what point the Al and Ag contacts become continuous on LiF, untreated, and coated samples. SEM data is the main means of assessment.

Device Properties—Device properties can be assessed in the benchmark OLED stack (Yu et al., J. Organomet. Chem. 2008, 693 (8), 1518-1527), shown in FIG. 1. Here the question is whether the coating protects the sample from deposition based damage. Substrates are prepared with 75 nm of ITO, 75 nm of NPB, 20 nm of Ir(mppy)₃, 100 nm TPBi, and 50 nm of Al. Devices undergo standard testing including measuring contact resistance, lifetime and external quantum efficiency. Helander et al., Science 2011, 332 (6032), 944-947. Devices with smaller TPBi layers are also prepared to demonstrate the ability to reduce the material needs. It is assumed that the introduction of an interfacial dipole (from the coating) in between the contact alters the contact resistance between TPBi and the top contact. Other compounds, such as ethylene sulfide, can be used for similar ring opening chemistry and these different dipoles to help minimize the contact resistance. Campbell et al., Phys. Rev. B 1996, 54 (20), R14321-R14324.

### Characterization

Full chemical and morphology analysis of the coated films described herein are obtained using polarization modulation infrared reflection absorption spectroscopy (PM-IRRAS), scanning electron microscope (SEM), energy dispersive X-ray spectroscopy (EDX), X-ray photoelectron spectroscopy (XPS), and mass spectrometry. See e.g., Deye et al., Molecular Surfaces. Langmuir 2017, 33 (33), 8140-8146; Deye et al., J. Phys. Chem. C 2018, 122 (27), 15582-15587; Qualizza et al., Chem. Commun. 2013, 49 (40), 4495-4497; and Piranej et al., CrystEngComm 2016, 18 (32), 6062-6068. Samples are examined for contact based damage using, for example, transition electron microscopy (“TEM”) and scanning electron microscopy (“SEM”). Optimized chemistry is then adapted into the representative OLED stack shown in FIG. 1.

### Aspects of the Disclosure

### Surface Layers of the Disclosure

The surface layers of the disclosure can improve two of the properties that limit organic semiconductors in OLEDs and OFETs, and as such simplistic devices have been fabricated to show that top contact metal penetration is eliminated and that carrier mobility is improved in OLED and OFET devices, respectively.

In some embodiments, disclosed herein is a new surface layer chemistry compatible with the molecular surface 2,2′,2″-(1,3,5-benzinetriyl)-tris(1-phenyl-1-H-benzimidazole) (TPBi). This chemistry utilizes the imidazole functionality found in this common electron transport layer material for ring opening chemistry with epoxides and episulfides. Rates, extent of surface coverage, and integrity of underlying TPBi film have been evaluated; x-ray photoelectron spectroscopy (XPS), polarization modulation infrared reflection absorption spectroscopy (PM-IRRAS), and energy dispersive X-ray (EDX) spectroscopy provide the majority of chemical characterization. Installed hydroxyl or thiol groups bind effectively to virtually any top metal contact.

Further disclosed herein are surface layers on TPBi that are used to reduce the metal penetration into the organic semiconductor, quantified by the maximum depth at which organic-metal intermixing is present. This “transition length” is evaluated via a depth profile establishing the location of the metal atoms at various heights in the sample. XPS provides the quantification while Ar⁺ ion etching allows sampling to occur at various heights. Simple metal-semiconductor-metal devices confirm the elimination of metal filaments, which cause shorting.

Diels-Alder surface layers on pentacene thin films can cause conductivity increases in a heretofore unknown mechanism. Accordingly, a series of dienophiles can examine whether the effects stem from the surface layer adding interfacial dipoles to existing charge traps or from changes to the film's morphology at grain boundaries (which similarly eliminate trap states). OFETs were prepared to determine whether the conductivity changes is from carrier mobility or carrier concentration increases.

### Current State of the Literature

Depositing a top metal contact, as shown in FIG. 8, is a fundamental challenge. Metal deposited on the top-most organic layer (i.e. the ETL) arrives at the surface with high kinetic energy due to the need to either vaporize or eject the materials from the source. Additionally, the materials deposit as atoms (or small clusters) and high amounts of condensation energy are given off during as they aggregate. Finally, due to their small size, the atoms can easily intercalate into the spaces between the molecules of the organic layer. These problems are intrinsic to vapor phase-metal deposition. They are also destructive. Contact deposition routinely leads to thermal damage to the organic material and often penetration of the metal through the organic layer. Metals have been reported to penetrate over 200 nm into the organic layer under normal deposition conditions. In the worst case scenario, the metal only begins to deposit on the surface when the organic film has been saturated with metal and organic layer is rendered non-functional (FIG. 7). Severe cases lead to complete OLED failure. Less severe cases generate up to 50% less light output and large efficiency decrease. Deposition conditions can alleviate (though not eliminate) the problem. Thicker layers are a common solution (the extra material receives the damage, protecting the underlying), but this represent a costly solution that also can adversely affect device performance.

Traditional solutions to the penetration problem have long been to introduce an interlayer on top of the ETL which impedes the penetration of the metal atoms. Acting as a physical impediment, this layer provides some relief. However, the ideal interlayer contains chemical functional groups which form a covalent bond with the deposited metal; this strong interaction eliminates metal penetration and ends diffusion. This finding has been established in a wide range of fields utilizing metalation. As a result, more than 20 metal inorganic interlayers have been tried as have physically deposited molecules containing heteroatoms (0, N). These layers reduce some of the metal penetration, but introduce new problems. These problems include the intermixing of these new layers with the ETL (for example CrOx is deposited via the same thermal process as the top contact), thermal damage, and the creation of additional electronic interfaces in the device. As a result, these technologies have not been adopted by industry.

The field of molecular electronics has shown that if an interlayer is designed correctly, it can eliminate penetration and have no adverse electronic effects. The surface layers of the disclosure are subject to three design rules. One, the added surface layer contains a metal-binding functional group that should be exposed at the top of the surface layer rather than embedded within. Two, the functional group is chosen to maximize the interaction/bond formed with the deposited metal. Three, the areal coverage of the metal-binding functional group over the surface is uniform and of high density. By meeting these criteria, the surface layers of the disclosure can facilitate formation of high quality metal contacts on top of the ETL layer.

The surface layers disclosed herein contain a high degree of tunability which is necessary to install the desired functional groups, and the specificity of the chemistry means that a surface layer of the disclosure can be designed where the functional groups are available at the surface. Their thickness (1-2 nm) minimizes overall change to the electronic band structure of the device and makes them ideal for these applications. There have been some initial attempts to functionalize organic semiconductors in this manner.

### Results: Reducing Metal Penetration in Top Contacts

Organic materials can be coated with interlayers approximately 1-2 molecules thick. For example, tetracene can be coated with a surface layer by various methods. The process disclosed herein alters only the topmost portion of the semiconductor and adds useful functional groups at the surface, but leaves the bulk properties of the semiconductor intact (FIG. 10). The process takes advantage of the inherent chemical reactivity specific to the organic semiconductors making masking unnecessary. The chemistry has been demonstrated on the prototypical transistor materials, pentacene and tetracene.

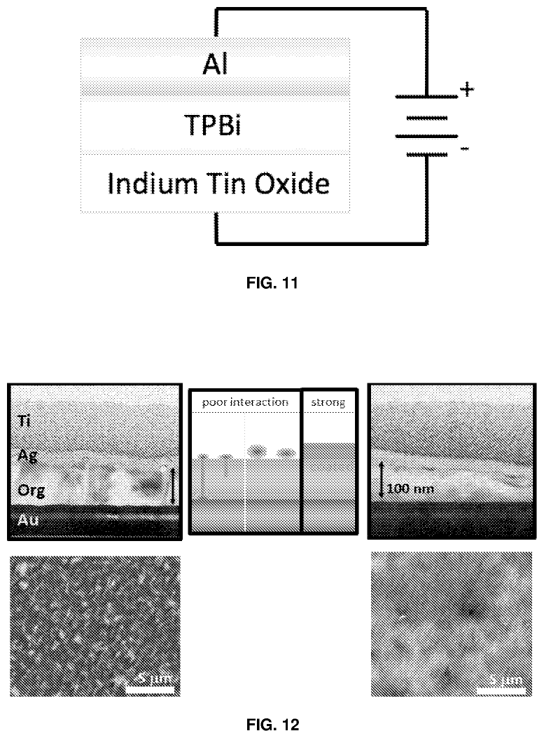

The coatings and their terminal chemical groups (spheroid shapes in FIG. 10) are designed to address issues that arise during the deposition of top metal contacts such as contact resistance and poor adhesion. Most notable, the coatings have been shown to reduce/eliminate the damage which occurs when top metal contacts are deposited onto organic semiconductor surfaces. On tetracene surfaces, it has been demonstrated that the coatings can virtually eliminate metal penetration into the semiconductor (FIG. 11, right and FIG. 16, top). Additionally, the metals contacts deposit in a uniform and consistent manner, in contrast to the untreated tetracene films (FIG. 16, bottom). The chemically created binding groups can be tailored to match the deposited metal and improve adhesion.

The technical challenge solved by the present disclosure is adapting ring opening chemistry to OLED ETL layers in order to eliminate metal penetration in prototype devices in a manner that meets the performance needs of existing manufacturers. Furthermore, the process is to be refined to be compatible with atomic layer deposition systems as these systems are utilized in some OLED fab lines. The conditions can be optimized to meet the stringent processing time allowed by industry (typically a total average cycle time (i.e., a TAC time, or how fast the process can be) of 3-6 minutes or less, ideally 1 minute).

In embodiments, the demonstrated chemistry is specific to the electron rich pi systems of tetracene, pentacene and other similar materials. Thus, a chemistry compatible with OLED ETL layers, specifically the ubiquitous 2,2′,2″-(1,3,5-benzinetriyl)-tris(1-phenyl-1-H-benzimidazole) (TPBi), has been developed. These layers can be used to eliminate metal penetration in in a model system.

### TPBi Surface Layer Chemistry: Rates, Coverages, & Subsurface Penetration

It has been found that TPBi surfaces can be reacted via a ring opening chemistry, where the nucleophilic nitrogen in the imidazole reacts with the less hindered position on the epoxide (propylene oxide). TPBi is one of the most common ETL layers used in industry and chemistry developed for these molecular materials is applicable to ETL layers such as bathocuproine (BCP) or other terminal OLED layers such as bathophenanthroline (BPhen), which contain the necessary nucleophilic nitrogen for the reaction. The basic ring opening reaction has been reported on 1,2-dimethylimidazole and 1,2-dimethylbenzimidazole, and the conditions therein require minimal modification to be applicable to TPBi. The disclosure herein first generates the standard solution-synthesized adduct along with ¹H, ¹³C, and IR spectroscopy to confirm the identity. The IR spectra of the standard solution-synthesized adduct is especially important; with analogous reactions on the surface of thin-films, diagnostic infrared signatures of the solution are used to generate standards to confirm the identity of new species in the thin films. The ring opening chemistry can be adapted to react with of surface. In some embodiments, a small amount of vapor of the adsorbate (i.e. propylene oxide) can be introduced to the thin-film (in this case it will be TPBi). Excess reactant can be removed after reaction by applying high vacuum.

In some embodiments, substrate molecules are in a locked configuration as part of the molecular lattice, and thus the approach of propylene oxide towards the reactive portions of the TPBi can be restricted. Many nuances regarding pentacene and tetracene have been found For example, surface adaption can involve the confirmation of reaction identity, a look at significant rate deviations, an assessment of reaction distribution, and a confirmation of substrate integrity, as described below.

### TPBi Protection Via Interlayer

Described herein is ring opening chemistry that coats ETL layers to eliminate damage caused by top contact deposition. The ring opening chemistry reacts with nitrogen containing molecules to leave a metal binding chemical group exposed at the surface, which can then form a bond at the top contact, similar to the approach in FIG. 12. TPBi is a representative ETL (FIG. 1) and can be reacted via its imidazole group. The approach described herein is general to any ETL layer containing this group. The approach described herein also is viable on ETL layers such as BCP or other terminal OLED layers such as BPhen, which contain the necessary nucleophilic nitrogen for the reaction.

Ring opening chemistry has been demonstrated to prevent metal penetration on thin films of TPBi. Optimized chemistry is then adapted into the representative OLED stack shown in FIG. 1 and primary performance metrics have been analyzed. These metrics are device driving voltage, external quantum efficiency, and lifetime as well as ETL materials reduction. Concurrently, the chemistry disclosed herein is adapted to atomic layer deposition systems, which are utilized in some OLED fab lines.

Preparatory Chemistry and Contacts with Minimal Metal Penetration

TPBi surfaces can be reacted via a ring opening chemistry, where the nucleophilic nitrogen in the imidazole reacts with the less hindered position on an epoxide ring (FIG. 14). The basic chemistry has been reported on 1,2-dimethylimidazole and 1,2-dimethylbenzimidazole and the conditions therein require minimal modification to be applicable to TPBi. The reaction identity, rate, and surface coverage of the molecular surfaces can be confirmed using known methods.

The ability of the chemically created interlayer to reduce metal penetration can be confirmed by thermally evaporating aluminum (a common OLED top contact). Three different substrates are compared: TPBi with a 5 nm layer of LiF thermally deposited, TPBi with our chemically created interlayer, and an untreated TPBi control. A depth profile establishing the location of the aluminum groups at various heights in the sample can be generated by XPS where Ar⁺ ions etch away the surface a nanometer at a time to give the transition length. Typical data (from reference 8) is shown in FIG. 17 where the Al signal is initially high (gray, nearly 100% atomic percentage) and then as the XPS begins to sample lower into the aluminum contact, the mixed interfacial later, and then the underlying organic semiconductor, the Al signal decreases, while the carbon content rises. The transition length (or amount the aluminum penetrates is the region from 80% metal to 20% metal) is used to quantify the extent of top contact penetration into the organic semiconductor.

### Confirming Reaction Identity; Rate of Surface Reaction

Because of the unusual environment experienced by the solid-phase materials, deviations from the desired reaction product and expected rates are sought. The former can be achieved with polarization modulation infrared reflection absorption spectroscopy (PM-IRRAS), a surface sensitive technique which allows chemical structure assignments. Here, measured infrared signatures can be compared to that of the standard solution-synthesized adduct. At least half of the most intense vibrations occur in a region that is free of signal from the TPBi substrate. Adduct formation can be confirmed as the major product if these diagnostic signals match new vibrations. Example analysis can be seen in FIG. 10. Mass spectrometry (typically MALDI) can complement this data. Thus, thin film samples of TPBi can be reacted with small amounts of propylene oxide vapors and utilize PM-IRRAS and mass spectrometry to confirm the identity of the products.

Reaction kinetics are one of the parameters that deviate the most when shifting from solution to surface reactions, as new structural factors become important. Previous results with pentacene and tetracene thin films suggest that rate data is somewhat independent of the strength of the intermolecular interactions within the film, but very dependent on molecular orientation at the surface (e.g. FIG. 14), and on defects for nucleating the chemistry on surfaces with unfavorable molecular orientation. Many of these finding are further supported by bulk reaction studies. Accordingly, the degree to which these factors impact reactivity for a wholly new surface reaction on a untested molecular surface (TPBi) have been examined. These studies are especially meaningful since the more globular and less rigid TPBi molecule is expected to impart significantly reduced orientation effects on the kinetics, while the smaller propylene oxide may intercalate more effectively to reach recessed reaction sites.

Relative rates of reactions can be measured on a single crystal (where molecular orientation at various faces can be assessed via x-ray diffraction) in order to determining how molecular orientation effects reactivity. Single crystals eliminate the role of defects on reactivity, allowing for simpler data analysis. Kinetics are determined by monitoring the elemental composition of the substrate via energy dispersive x-ray (EDX) spectroscopy, which can then be mapped onto the crystal images provided by SEM. Crystal images are identical to those taken by the x-ray diffractometer (XRD) when indexing the crystal. As such, correlating molecular orientation to reactivity is straightforward. Because the effects or orientation on a well-ordered crystal system is understood, thin films (with the added complexity of defects) can be analyzed. The role of defects can be assessed by tuning the grain sizes (and thus grain boundary density) by controlling film deposition temperatures. In embodiments, EDX can be used for its ability to quantify the change, while complementary spectroscopic assignments (PM-IRRAS) allow for a real time quantification of the reaction. Thus, single crystals of TPBi were grown and reacted with propylene oxide, and the different reactivities at different crystal faces (via EDX, XRD) can be examined via molecular orientation at the surface. When crystals are understood, thin-films of TPBi can be grown with different grain sizes to examine of defects (grain boundaries) effect reaction rates.

### Surface Coverage Assessment

The surface layer's ability to prevent metal penetration is a function of its areal density and uniformity. The most accurate measure of areal density is XPS. For XPS the sampling depth is adjustable between 1 and 5 nm depending on the angle of the detector, and thus it can provide accurate quantification of the surface coverage after reaction. The measured O 1 s signal from the added chemical group can be compared to the N 1 s signal from the TPBi to determine the number of oxygen per molecule at the surface. These values can be readily converted to atoms/cm³ as the surface density of TPBi is determined. Coverage uniformity can be analyzed down to about 10 μm in SEM by mapping EDX data across the surface. In embodiments, nanoscale coverage can be assessed via a Neaspec NanoFTIR/NIM AFM. Thus, the same thin films prepared for the rate measurements can be used to determine the surface density of oxygen atoms per TPBi molecule (XPS), while uniformity of coverage is determined via EDX.

### Substrate Integrity

A surface layer of the disclosure should generate minimal change to the bulk TPBi substrate. Due to the small size of the adsorbate, a significant amount of propylene oxide could potentially penetrate into the subsurface (either reacted, or unreacted). If this occurs to a significant extent (>50% reacted at 3 nm sample depth), bulkier adsorbates can be used, such as phenyl oxiranes. PM-IRRAS is ideal for assessing film consumption as disappearance of TPBi stretches can be monitored and the percentage of the substrate reacted can be quantified. EDX measurements at higher acceleration voltages provide elemental information for the underlying surface which can confirm its integrity. If these preliminary indicators cannot rule out subsurface TPBi reaction, a depth profile measuring the density of the oxygen groups at various heights in the sample can be generated by XPS where Ar⁺ ions etch away the surface a nanometer at a time. Thus, thin films prepared for rate measurements to screen for subsurface reaction (PM-IRRAS, EDX) have been examined. Samples flagged in the initial screen are fully analyzed via a depth profile XPS measurements. Alternative molecules (phenyl oxiranes) can avoid damage if needed.

### Minimized Metal Penetration for Improved Device Performance

Metal contacts deposited on TPBi can be significantly improved via the use of a chemically created surface layer on top of the TPBi, which will covalently bond to the incoming metal. In embodiments, thermal evaporation of aluminum (a common OLED top contact) is used to measure the extent of metal penetration into the TPBi film, and its performance is subsequently looked at in a simple a metal-semiconductor-metal device. The chemically created interlayer is compared to untreated substrates and substrates with a thin (1 nm) layer of LiF to assess the effect of chemically created interlayers on the top contact. While effective at lowering metal penetration, LiF has not found widespread use in industry due to its propensity to generate diffusive lithium which migrates through the semiconductor.

In embodiments, a chemically created interlayer on the ETL of a standard OLED stack (ITO (75 nm)/NPB (75 nm)/Ir(mppy)3 (20 nm)/TPBi (100 nm)/Al (50 nm)) is generated and the ability of the interlayer to generate comparable device performance utilizing progressively thinner ETL layers (100, 80, 50, and 20 nm) is demonstrated.

In embodiments, rapid reaction conditions compatible with an atomic layer deposition (ALD)-like system are generated that mimic industrial production. Processing time must be reduced (sub 6 minutes) to be economically viable industrial production.

### Minimized Metal Penetration for Improved Device Performance

The surface layer and methods of the disclosure improves metal contacts deposition on TPBi. The surface layer is compared to untreated substrates and substrates with a thin (1 nm) layer of LiF to assess the effect of chemically surface layers on the top contact. LiF is the academic standard layer for treating eliminate contact issues (section 2.5) and will serve as a reference.

Device properties can be assessed in the benchmark OLED stack shown in FIG. 18. Here the chemically deposited interlayer is tested for its ability to improve device performance by eliminating metal penetration. Substrates are prepared with 75 nm of ITO, 75 nm of NPB, 20 nm of Ir(mppy)₃ doped into mCP, 100 nm TPBi, and 50 nm of Al. Devices undergo standard testing including measuring the drive voltage, lifetime, and external quantum efficiency. Performance metrics of the chemically created interlayer should match or exceed the untreated control and the LiF standard. Using the data generated, samples with successively thinner TPBi layers can be constructed (80 nm, 50 nm, 20 nm). These devices are tested in a similar manner and demonstrate the ability to reduce the material needed in devices manufactured by our potential commercialization partner. Important measured metrics include threshold and operating voltages, external quantum efficiency (EQE), lifetime (t₅₀), TPBi reduction.

### Metal Penetration Analysis

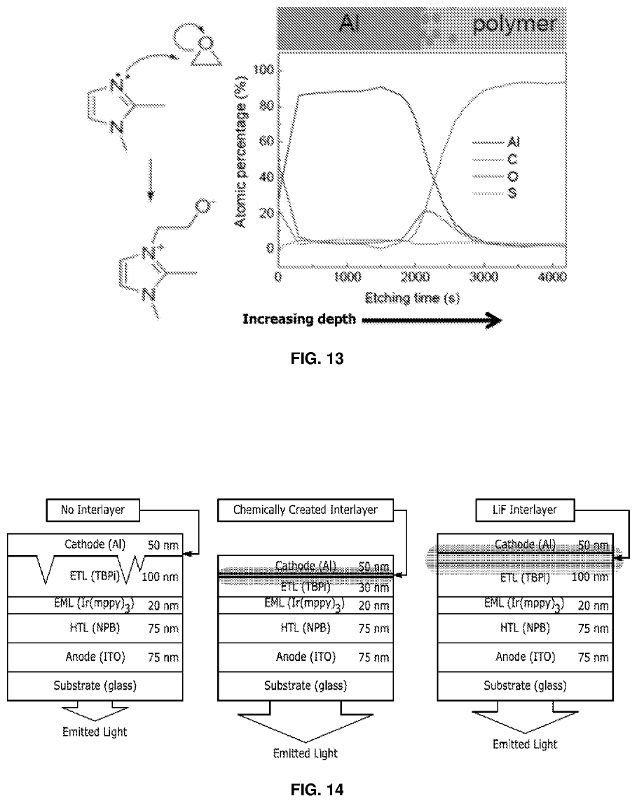

The chemistry described herein can be applied to a substrates consisting of 100 nm of TPBi on gold. The simplified system allows clearer imaging of the metal organic interface formed by the deposition of a top contact. Three different substrates have been compared: TPBi with a 5 nm layer of LiF thermally deposited, TPBi with a surface layer of the disclosure, and an untreated TPBi control. All were capped with thermally deposited aluminum. A depth profile establishing the location of the aluminum groups at various heights in the sample was generated by XPS where Ar⁺ ions etch away the surface a nanometer at a time to give the average penetration depth of metal. Typical data (from reference 34) is shown in FIG. 13 where the Al signal is initially high (gray, nearly 100% atomic percentage) and then as the XPS begins to sample lower into the aluminum contact, the mixed interfacial later, and then the underlying organic semiconductor, the Al signal decreases, while the carbon content rises. The transition length (or amount the aluminum penetrates is the region from 80% metal to 20% metal) is used to quantify the extent of top contact penetration into the organic semiconductor. In embodiments, the different surface densities of the surface layers disclosed herein are measure by looking at various samples to correlate the surface layer coverage to the extent of metal penetration. Results are then compared to the LiF and untreated samples to reference improvement against current best interlayer and unimproved samples respectively. Based on prior results with tetracene/pentacene (FIG. 12), the surface layers of the disclosure can be highly effective in eliminating metal penetration. In some embodiments, epoxides containing additional oxygen groups (e.g. glycidol) can be used, or a second step to chemically transform the surface layer can be added to increase the functional group density at the surface. Thus, the thin films samples described herein can be reacted during the density study disclosed herein, aluminum can be thermally deposited on them, and the depth that the aluminum contact penetrates into the semiconductor (the transition length, via XPS) can be compared to a control sample of containing only TPBi, and TPBi with a LiF interlayer.

### Metal-Semiconductor-Metal Device Measurements

Penetration analysis is a direct measure of the amount of metal which diffuses into the organic semiconductor. Unfortunately it provides only indirect information on how the metal impacts device performance. As discussed above, top contact penetration can lead to shorting of devices, even if only a single filament is generated. It is not just the amount of metal, but the pathways it forms, and even amounts of metal undetectable by XPS are capable of rendering OLEDs non-functional. Device performance can be approximated via a simple metal-semiconductor-metal configuration (FIG. 11). These devices, though similar in composition to penetration samples (Au-TPBi-Al) involve patterning accomplished via shadow masks similar to the devices we generated in FIG. 5. The masks permit generation of 10-20 of devices per sample. Electrical contact can be made directly via probes or using eutectic gallium-indium which provides a gentler means of contact.⁵³

Devices can be analyzed using simple current (1)-voltage (V) measurements. A well-formed interface between the top contact and the organic semiconductor should generate current profile of a classic Schottky barrier to charge injection. In contrast, the presence of even a single filament bridging the semiconductor raises the current level from an expected 10⁻⁷ amps to value greater than 10⁻³ amps. Partially formed filaments generate current levels in between. The current levels provide direct quantification of the effect of penetration OLED performance, and can be correlated with the transition length (see above) to provide a full picture of the surface layers effect. Performance is then compared to that of the LiF sample. In some embodiments, the I-V data can be used to allow the quantification of charge injection barriers, and an understanding of how they are modified by the interfacial dipoles generated between the metal contact which is bonded to the surface layer. Such data has implications for minimizing contact resistance inherent in OLED devices. Thus for the concluding experiments for TPBi, Au-TPBi-Al layered devices are prepared using shadow masks and current (I)-voltage (V) behavior is measured for these devices. The ability of surface layer coated TPBi to prevent top contact shorting of devices is compared to that of a control sample containing only TPBi, and TPBi with a LiF interlayer.

Reducing TAC time and Configuring for Industrial Tools

The reaction conditions disclosed herein can be optimized for compatibility with industrial partners. Specifically, processing time can be reduced to 3-6 minutes while operating within a temperature range. Towards the specific goal of industry application, process temperatures and pressures are adjusted in a system that mimics fabrication line conditions.

The chemistry described herein can be transferred from research conditions to production conditions to make significant gains in processing speed. With each piece of processing equipment in a generation 8 fabrication facility costing $300-600 M dollars, it is important to processes the maximum square footage of display in the minimum time possible. Accordingly industry sets a general target of 3-6 min per process (also known as TAC time), with a targeted value of 1 min. The reaction kinetics indicate that a chemically created interlayer can be generated in that time and thus process temperatures and pressures of the reactions described herein can be optimized.

A high vacuum system that mimics an atomic layer deposition tool can be constructed. This tool rapidly doses in the reactive gas at elevated temperatures with a controllable pressure. The vacuum system allows 1) introduction and removal or chemicals in seconds, 2) fine control over the amount of chemical precursor added via pressure/dosing valves 3) independent control over the temperature of the surface and the reaction chamber (which can minimize the temperature that the underlying OLED materials are exposed to). OLED devices typically have a thermal budget of minutes at 100° C., and thus the upper reaches of that limit are screened for conditions that allow rapid processing of substrates. Alternative reactants (e.g. episulfides) represent an alternative approach control over substrate and gas temperature (as well as pressure) prevent rapid reaction at modest temperatures. A maximum TAC time of 6 minutes must be reached.

### EXAMPLES

### Example 1

Films prepared according to the present disclosure include TPBi layer deposited via thermal evaporation directly on rigid substrates (e.g. glass, silicon, quartz) or flexible substrates (e.g. polyethylene teraphthalate (PET)) on either the bare substrate or with a conductive backing (e.g. indium tin oxide (ITO) or gold with a chromium adhesion layer), b) TPBi deposited via thermal evaporation as part of a representative OLED stack such as shown in FIG. 1, c) films as described in a) and b) wherein the TPBi is deposited via spin coating (e.g. from a 0.4 wt % solution of methanol) or other solution based method as opposed to thermal evaporation. In these examples, TPBi can be replaced as the ETL by BPhen, BCP, or the other suitable compounds disclosed herein. A suitable benzimidazole as disclosed herein includes 1-(2-Hydroxypropyl)-2,3-dimethylbenzimidazolium Chloride, which can be prepared as described in Example 2 below.

The films listed above were modified by placing the substrate in one end of glassware (e.g. a Schlenk tube) while the molecule containing the oxiranyl, aziridinyl, or thiiranyl ring is placed in the opposite side. The glassware was sealed under nitrogen and heated to 40, 60, 80, 100° C., or another suitable temperature for a time ranging from 1 minute to 48 h. After reaction, the residual vapor from the molecule was condensed away from the film by locally cooling one end of the tube, before the substrate was removed.

Films disclosed herein are also modified by placing the substrate in an ALD (atomic layer deposition) chamber whereby the molecule containing the oxiranyl, aziridinyl, or thiiranyl ring is introduced into the reaction chamber and heated to 40, 60, 80, 100° C., or another suitable temperature for a time ranging from 1 minute to 48 h. Residual vapors are removed via vacuum.

Films disclosed herein are also modified by placing the substrate near an evaporator, spray nozzle, or other suitable depositing means which places a coating of the molecule containing the oxiranyl, aziridinyl, or thiiranyl ring on the substrate. The substrate is then warmed for 40, 60, 80, 100° C., or another suitable temperature for a time ranging from 1 minute to 48 h. Residual vapors are removed via vacuum.

Films disclosed herein are also modified by applying the nitrogen-containing heterocycle to the substrate via solution casting, spin coating, inject printing or a similar method. In this method, the molecule containing the oxiranyl, aziridinyl, or thiiranyl ring is dissolved in an orthogonal solvent which does not dissolve the thin film. The substrate is warmed for 40, 60, 80, 100° C., or another suitable temperature for a time ranging from 1 minute to 48 h. Residual vapors are removed via vacuum.

In each of these examples, the substrate is optionally preexposed to HCl gas or solution, to first protonate the thin film.

In one instance, silicon slides were cleaned with piranha solution (1:1 H₂SO₄:H₂O₂) for 15 min before TPBi was deposited on a home built sublimation chamber at pressure of less than <10⁻⁵ Torr and a rate of 1 Å/s. TPBi was deposited to a thickness of 100 nm. The TPBi thin film was placed in a Schlenk tube under nitrogen. Propylene oxide (10 μL) was added to the opposite end of the tube, and the tube was sealed and heated to 40° C. for 24 h. The sample was removed and placed under high vacuum (<10⁻⁵ Torr) for 30 min. The substrate was characterized by energy dispersive X-ray spectroscopy (EDX) showing an oxygen percentage of 6-7% corresponding to roughly 3 propylene oxides per TPBi molecule (at 1 keV energy). At higher beam voltages, oxygen percentages decreased to 4% (1.5 keV) and 3% (2 keV) showing the underlying TPBi remains mostly unreacted. Control samples (10 μL ether or no added molecule) show an oxygen percentage only slightly more than background (2% or less).

### Example 2

### Synthesis of 1-(2-Hydroxypropyl)-2,3-dimethylbenzimidazolium Chloride

1,2-dimethylbenzimidazole (0.1996 g, 1.37 mmol) and ethanol (0.30 ml) were stirred in a Schlenk tube for 15 minutes at room temperature, under ambient atmosphere, in a water bath. To the stirring solution was added, dropwise, 12 M hydrochloric acid (0.12 ml, 1.44 mmol). The exothermic reaction was allowed to cool to room temperature, after which N₂ gas was blown over the solution. Propylene oxide (0.1 ml, 1.43 mmol) was added to the Schlenk tube, and the tube was immediately sealed and placed into a hot oil bath and heated steadily at 45° C. The solution was allowed to stir for 24 hours and the reaction was monitored by NMR. The crude product was transferred to a round bottom flask, and the solvent was removed as the flask was placed under reduced pressure and heated to 80° C. The resulting solid was further dried under N₂ gas.

1H NMR (500 MHz, D₂O): δ 1.33 (d, 3H, J=6 Hz), 2.87 (s, 3H), 3.98 (s, 3H), 4.27 (m, 1H), 4.38 (dd, 1H, J=8 Hz), 4.51 (dd, 1H, J=3 Hz), 7.62 (m, 2H), 7.79 (m, 2H). 13C NMR (125 MHz, D₂O): δ 10.3, 19.3, 31.3, 51.7, 65.7, 112.3, 112.6, 126.2 (2), 131.2, 131.5, 151.6.

Unless defined otherwise, all technical and scientific terms used herein have the same meaning as commonly understood by one of ordinary skill in the art to which this disclosure pertains.

Ranges may be expressed herein as from “about” or “approximately” one particular value and/or to “about” or “approximately” another particular value. When such a range is expressed, another embodiment according to the disclosure includes from the one particular value and/or to the other particular value. Similarly, when particular values are expressed as approximations, by use of antecedents such as “about,” “at least about,” or “less than about,” it will be understood that the particular value forms another embodiment.

### REFERENCES

1. Display Supply Chain Consultants. OLED Shipment & Fabrication. (2019).
2. Sirringhaus, H. Adv. Mater. 26, 1319-1335 (2014).
3. Turak, A. RSC Adv. 3, 6188-6225 (2013).
4. Veerbeek, J. et al. Small Methods 1, 1700072 (2017).
5. Gardner, T. J. et al. Systems for orthogonal self-assembly of electroactive monolayers on Au and ITO: an approach to molecular electronics. J. Am. Chem. Soc. 117, 6927-6933 (1995).
6. Kelley, T. W. et al. J. Phys. Chem. B 107, 5877-5881 (2003).
7. Nuzzo, R. G. et al. J. Am. Chem. Soc. 105, 4481-4483 (1983).
8. Paniagua, S. A. et al. Chem. Rev. 116, 7117-7158 (2016).
9. Zojer, E. et al. Adv. Mater. Interfaces 6, 1900581 (2019).
10. Zhang, X. et al. Small 15, 1900332 (2019).
11. Don Park, Y. et al. Mater. Today 10, 46-54 (2007).
12. Vollmer, A. et al. Eur. Phys. J. E 17, 339-343 (2005).
13. Calhoun, M. F. et al. Nat. Mater. 7, 84-89 (2008).
14. Yoo, S. H. et al. Nanoscale Res. Lett. 6, 1-7 (2011).
15. Piranej, S. et al. CrystEngComm 18, 6062-6068 (2016).
16. Li, F. et al. RSC Adv. 9, 26942-26948 (2019).
17. Qualizza, B. A. et al. Chem. Commun. 49, 4495-4497 (2013).
18. Deye, G. J. et al. Langmuir 33, 8140-8146 (2017).
19. Deye, G. J. et al. J. Phys. Chem. C 122, 15582-15587 (2018).
20. Li, F. et al. Chem. Commun. Rev. (2019).
21. OLED Fundamentals: Materials, Devices, and Processing of Organic Light-Emitting Diodes. (CRC Press, 2015).
22. Fleming, I. Pericyclic reactions. (Oxford University Press, 1999).
23. Nakamatsu, S. et al. Chem. Commun. 3808-3810 (2005).
24. Monas, A. et al. Chem. Commun. 52, 12960-12963 (2016).
25. Gao, Y. Mater. Sci. Eng. R Rep. 68, 39-87 (2010).
26. Angel, F. A. et al. Org. Electron. 42, 102-106 (2017).
27. Tang, J. X. et al. J. Appl. Phys. 95, 4397-4403 (2004).
28. Gao, Z. Q. et al. Appl. Phys. Lett. 74, 3269-3271 (1999).
29. Janssen, F. J. J. et al. Phys. Rev. B70, 165425 (2004).
30. Dürr, A. C. et al. Adv. Mater. 14, 961-963 (2002).
31. Dürr, A. C. et al. J. Appl. Phys. 93, 5201-5209 (2003).
32. de Boer, B. et al. Langmuir 20, 1539-1542 (2004).
33. Burkstrand, J. M. J. Appl. Phys. 52, 4795-4800 (1981).
34. Wang, M. et al. Sol. Energy Mater. Sol. Cells 95, 3303-3310 (2011).
35. Bain, C. D. et al. J. Am. Chem. Soc. 110, 5897-5898 (1988).
36. Herdt, G. C. et al. Prog. Surf. Sci. 50, 103-129 (1995).
37. Herdt, G. C. et al. J. Adhes. 60, 197-222 (1997).
38. Popoff, R. T. W. et al. J. Phys. Chem. C 116, 17040-17047 (2012).
39. Ellison, D. J. et al. Adv. Mater. 23, 502-507 (2011).
40. Piranej, S. et al. Submitt. Cryst. Growth Des. (2019).
41. Holbrey, J. et al. (2005).
42. Wang, Y.-B. et al. Green Chem. 16, 2266-2272 (2014).
43. Singh, N. B. et al. Tetrahedron 50, 6441-6493 (1994).
44. Gavezzotti, A. J. Am. Chem. Soc. 105, 5220-5225 (1983).
45. Braga, D. et al. Crystal Design: Structure and Function (ed. Desiraju, G. R.) 325-373 (John Wiley & Sons, Ltd, 2003).
46. Paul, I. C. et al. Science 187, 19-26 (1975).
47. Kaupp, G. et al. Mol. Cryst. Liq. Cryst. Sci. Technol. Sect. Mol. Cryst. Liq. Cryst. 276, 315-337 (1996).
48. Kalihari, V. et al. Adv. Mater. 20, 4033-4039 (2008).
49. Modern ESCAThe Principles and Practice of X-Ray Photoelectron Spectroscopy. CRC Press Available at: https://www.crcpress.com/Modern-ESCAThe-Principles-and-Practice-of-X-Ray-Photoelectron-Spectroscopy/Barr/p/book/9780849386534. (Accessed: 28th Jun. 2019)
50. Stine, R. et al. Langmuir 28, 7957-7961 (2012).
51. Parthasarathy, G. et al. J. Appl. Phys. 89, 4986-4992 (2001).
52. Nicosia, C. et a. Mater. Horiz. 1, 32-45 (2014).
53. Chiechi, R. C. et al. Angew. Chem. Int. Ed. 47, 142-144 (2008).
54. Campbell, I. H. et al. Phys. Rev. B54, R14321-R14324 (1996).
55. Brédas, J. L. et al. Proc. Natl. Acad. Sci. 99, 5804-5809 (2002).
56. Matsubara, R. et al. Appl. Phys. Lett. 92, 242108 (2008).
57. Hasegawa, T. et al. Sci. Technol. Adv. Mater. 10, (2009).
58. Bittle, E. G. et al. Nat. Commun. 7, 10908 (2016).
59. Spindler, J. P. et al. Handbook of Advanced Lighting Technology (eds. Karlicek, R., Sun, C.-C., Zissis, G. & Ma, R.) 1-21 (Springer International Publishing, 2014).
60. Vladimirov, I. et al. Sci. Rep. 8, 1-10 (2018).
61. Zuo, G. et al. J. Phys. Chem. C 121, 7767-7775 (2017).
62. Cooke, M. J. Semiconductor Devices. (Pearson Higher Education, 1990).
63. Levesque, P. L. et al. Nano Lett. 11, 132-137 (2011).
64. Kobayashi, S. et al. Nat. Mater. 3, 317-322 (2004).
65. U.S. Pat. No. 9,991,444 B2.
66. Display Supply Chain Consultants. Quarterly OLED Shipment and Fab Utilization Report; 2018.
67. Display Supply Chain Consultants. Quarterly OLED Materials Report; 2018.
68. Department of Energy. 2018 Solid-State Lighting R&D Opportunities; 2019; p 90.
69. Scholz, S. et al. J. Appl. Phys. 2008, 104 (10), 104502. https://doi.org/10.1063/1.3018716.
70. Turak, A. et al. Appl. Phys. Lett. 2002, 81 (4), 766-768. https://doi.org/10.1063/1.1494470.
71. Love, J. C. et al. Chem. Rev. 2005, 105 (4), 1103-1170. https://doi.org/10.1021/cr0300789.
72. Arnold, R. et al. Langmuir 2001, 17 (16), 4980-4989. https://doi.org/10.1021/la0102020.
73. Dürr, A. C. et al. J. Appl. Phys. 2003, 93 (9), 5201-5209. https://doi.org/10.1063/1.1556180.
74. Feifei Li et al. Submitt. Langmuir 2019.
75. OLED Fundamentals: Materials, Devices, and Processing of Organic Light-Emitting Diodes, 1 edition.; Gaspar, D. J., Polikarpov, E., Eds.; CRC Press: Boca Raton, Fla., 2015.

1. A surface-modified electron transport layer (“ETL”) of an organic light-emitting diode (“OLED”), the ETL comprising a ring-opening reaction product between a nitrogen-containing heterocycle of the ETL and one or more of an optionally substituted three-membered ring selected from the group consisting of an oxiranyl ring, an aziridinyl ring, and a thiiranyl ring.

2. The ETL of claim 1, wherein the nitrogen-containing heterocycle is an imidazole or a phenanthroline.

3. The ETL of claim 1, wherein the ring opening product comprises a monomer of the optionally substituted three-membered ring.

4. The ETL of claim 1, wherein the ring opening product comprises a dimer of the optionally substituted three-membered ring.

5. The ETL of claim 1, wherein the ring opening product comprises a trimer of the optionally substituted three-membered ring.

6. The ETL of claim 1, wherein the ring opening product comprises a tetramer of the optionally substituted three-membered ring.

7. The ETL of claim 1, wherein the ETL is substantially free of a polymerization product between the nitrogen-containing heterocycle of the ETL and the optionally substituted three-membered ring.

8. The ETL of claim 1, wherein the ETL comprises:
an ETL surface layer comprising a surface layer of the ring-opening reaction product; and
an ETL bulk layer substantially free from the ring-opening reaction product.

9. The ETL of claim 1, wherein the OLED comprises a cathode layer in direct contact with the ETL, the cathode layer comprising a metal atom bonded to the ring-opening reaction product of the ETL.

10. The ETL of claim 9, wherein the ETL comprises:
an ETL surface layer comprising a surface layer or bilayer of the ring-opening reaction product; and
an ETL bulk layer substantially free from the ring-opening reaction product and metal atoms of the cathode layer.

11. The ETL of claim 1, wherein the ring-opening reaction product is between the nitrogen-containing heterocycle of the ETL and an optionally substituted oxiranyl ring.

12. The ETL of claim 11, wherein the metal atom is selected from the group consisting of magnesium, calcium, aluminum, silver, copper, and combinations thereof.

13. The ETL of claim 1, wherein the ring-opening reaction product is between the nitrogen-containing heterocycle of the ETL and an optionally substituted aziridinyl ring.

14. The ETL of claim 13, wherein the metal atom is selected from the group consisting of gold, silver, and combinations thereof.

15. The ETL of claim 1, wherein the ring-opening reaction product is between the nitrogen-containing heterocycle of the ETL and an optionally substituted thiiranyl ring.

16. The ETL of claim 15, wherein the metal atom is selected from the group consisting of gold, silver, and combinations thereof.

17. The ETL of claim 1, wherein the nitrogen-containing heterocycle is an imidazole.

18. The ETL of claim 17, wherein the imidazole comprises 2,2′,2″-(1,3,5 benzinetriyl)-tris(1-phenyl-1-H-benzimidazole) (“TPBi”).

19. The ETL of claim 1, wherein, the nitrogen-containing heterocycle is a phenanthroline.

20. The ETL of claim 19, wherein the phenanthroline comprises bathocuproine (“BCP”) or bathophenanthroline (“BPhen”).

21. The ETL of claim 1, wherein the surface layer is a monolayer or a bilayer.

22. The ETL of claim 1, wherein the ETL is about 2 to 50 nm thick.

23. The ETL of claim 22, wherein the ETL is about 2 to 10 nm thick.

24. A method of preparing the surface-modified ETL of claim 1, comprising contacting a nitrogen-containing heterocycle of the ETL with an optionally substituted oxiranyl ring, an optionally substituted aziridinyl ring, or an optionally substituted thiiranyl ring in a ring opening reaction to form the surface-modified ETL.

25. The method of claim 24, wherein the nitrogen-containing heterocycle is an imidazole.

26. The method of claim 25, wherein the imidazole comprises 2,2′,2″-(1,3,5 benzinetriyl)-tris(1-phenyl-1-H-benzimidazole) (“TPBi”).

27. The method of claim 24, wherein the nitrogen-containing heterocycle is a phenanthroline.

28. The method of claim 27, wherein the phenanthroline comprises bathocuproine (“BCP”) or bathophenanthroline (“BPhen”).
